(19) United States
(12) Patent Application Publication
(10) Pub. No.: US 2006/0162863 A1
(43) Pub. Date: Jul. 27, 2006

(54) Semiconductor plasma-processing apparatus and method

(76) Inventors: Hyung-Joon Kim, Pyeong Taek-city (KR); Ki-Yung Lee, YeoSu-city (KR)

Correspondence Address: HARNESS, DICKEY & PIERCE, P.L.C., P.O. BOX 8910, RESTON, VA, 20195, US

(21) Appl. No.: 11/332,169

(22) Filed: Jan. 17, 2006

(30) Foreign Application Priority Data
Jan. 21, 2005 (KR) 10-2005-0005790

(51) Int. Cl. C23F 1/00; B44C 1/22; H05H 1/24; H01L 21/302; C23C 16/00

(52) U.S. Cl. 156/345.35; 216/68; 427/569; 438/710; 118/723 I; 156/345.48

(57) ABSTRACT

A semiconductor plasma-processing apparatus smoothes effects of side radical-concentration, which are frequently generated by inductive-coupling plasma sources, enhancing the etching uniformity therein. The apparatus includes a remote plasma generator providing lots of radicals and ions from activating processing gas; a reaction chamber having an inflow port through which the activated processing gas; a susceptor, on which a wafer is settled, disposed in the reaction chamber; and an inductive-coupling plasma generator disposed in the reaction chamber, providing high-frequency energy to the activated processing gas. As radicals and ions are affluently generated enough to conduct an etching process, by means of the remote and inductive-coupling plasma sources, the reaction sprightly proceeds to improve the etching efficiency.

### CROSS-REFERENCE TO RELATED APPLICATIONS

This U.S. non-provisional patent application claims priority under 35 U.S.C. § 119 of Korean Patent Application 2005-05790 filed on Jan. 21, 2005, the entire contents of which are hereby incorporated by reference.

### BACKGROUND

The subject matter described herein is concerned with plasma-processing apparatuses. In particular, the subject matter described herein relates to a semiconductor plasma-processing apparatus and method enhancing the etching uniformity by smoothing effects of side radical concentration that are frequently generated in inductive-coupling plasma sources.

With advancements of semiconductor devices toward higher integration, larger wafer size, larger area of LCD, and so forth, there are increasing on demands for high-performance apparatuses to treat an etching process or films. It is also for various kinds of plasma-processing apparatuses for plasma-etching, plasma-enhanced CVD, and plasma-ashing. In other words, those apparatuses are becoming influentially important in implementing clean environments and corresponding to the recent drifts with high-degree plasma and large-area subjects (e.g., large-size semiconductor wafer, or glass substrate) for extending throughput.

There are various kinds of plasma sources to be used in those plasma-processing apparatuses, such as a high-frequency capacitive-coupling plasma source, a microwave ECR plasma source, and a high-frequency inductive-coupling plasma source. The plasma sources are differently used in correspondence with kinds of processes, being suitable for their properties.

Among them, the plasma-processing apparatus using the high-frequency inductive-coupling plasma source is able to generate high-density plasma relatively under low pressure of several mTorr by just using the configuration of simplicity and low cost with antenna and high-frequency power. And, as coils thereof are arranged in the pattern of plane to a subject, it is easy to generate plasma in a wide area. Further, since a processing chamber has a simple internal structure, it is able to reduce particles flying over the subject during an etching process. Thus, the plasma-processing apparatuses each using the high-frequency inductive-coupling plasma source are widely spreading over the semiconductor manufacturing industries with those advantages.

Here, the inductive-coupling plasma source as a conventional plasma source is composed of a single plasma source. In other words, an RF antenna connected to an RF power unit is a single type installed at the outside of the processing chamber, by which the gas in the processing chamber is transformed into plasma by electric fields formed along the RF antenna. During this, electric fields generated from the sides of the processing chamber are overlapped with each other at the center thereof, by which ionic density of the plasma at the center is higher than those at the side parts therein while radical distribution is conditioned in the reverse. As a result, the reaction in the etching process is promoted by radicals' chemical energy and ions' physical energy. If the radical distribution is irregular, the chemical reaction becomes unequal to degrade the etching uniformity. Further, if there are insufficient quantities of radicals, an etching rate would be reduced.

### SUMMARY OF THE INVENTION

Accordingly, the invention is directed to solve the conventional problems aforementioned, providing a semiconductor plasma-processing apparatus and method capable of improving the etching uniformity with regulating the distribution of radicals.

The invention is also directed to a semiconductor plasma-processing apparatus and method capable of improving an etching rate, for which lots of radicals and ions generated by activating the processing gas just before supply to a processing chamber are supplied to the processing chamber.

An aspect of the invention is a semiconductor plasma-processing apparatus including: a remote plasma source activating processing gas to generate radicals and ions; a processing chamber having an inlet port through which the activated processing gas flows into; a susceptor disposed in the processing chamber, on which a wafer is settled; and an inductive-coupling plasma source disposed in the processing chamber, providing high-frequency energy to the activated processing gas.

In the embodiment, the inductive-coupling plasma source includes: a coil antenna surrounding an upper sidewall of the processing chamber; and an RF power unit applying RF power to the coil antenna.

In the embodiment, the semiconductor plasma-processing apparatus may further include a gas distribution plate uniformly supplying an inert gas into the processing chamber and having a gas inlet port disposed at the top of the processing chamber, through which the inert gas is supplied.

In the embodiment, the gas distribution plate comprises a path directly supplying the activated processing gas to the processing chamber from the remote plasma source.

The invention also provides a semiconductor plasma-processing apparatus including: a processing chamber including a susceptor on which a wafer is settled; a first plasma source generating plasma from processing gas before supplying the processing gas into the processing chamber; and a second plasma source generating plasma from the processing gas that is supplied into the processing chamber after passing through the first plasma source.

In the embodiment, the first plasma source is a remote plasma source generating radicals by activating the processing gas.

In the embodiment, the first plasma source includes: a coil antenna surrounding an upper sidewall of the processing chamber; and an RF power unit applying RF power to the coil antenna.

In the embodiment, the semiconductor plasma-processing apparatus further includes a gas distribution plate disposed at the top of the processing chamber, uniformly supplying the inert gas into the processing chamber.

In the embodiment, the semiconductor plasma-processing apparatus may further include a gas distribution plate uniformly supplying an inert gas into the processing chamber and having a gas inlet port disposed at the top of the processing chamber, through which the inert gas is supplied.

In the embodiment, the gas distribution plate includes a path directly supplying the activated processing gas to the processing chamber from the first plasma source.

Another aspect of the invention is a method of processing plasma for a semiconductor manufacturing process, comprising: supplying inactivated processing gas into a remote plasma source; supplying radicals and ions, which are excited in the remote plasma source, into a processing chamber; supplying inactivated inert gas into the processing chamber; and activating the radicals and ions and the inert gas, which are being supplied into the processing chamber, by an inductive-coupling plasma source.

In the method, the inactivated inert gas is uniformly supplied into the processing chamber through a gas distribution plate.

In the method, the radicals and ions are supplied into the processing chamber from the remote plasma source, being different from the inert gas in path.

### BRIEF DESCRIPTION OF THE FIGURES

The accompanying drawings are included to provide a further understanding of the invention, and are incorporated in and constitute a part of this specification. The drawings illustrate example embodiments of the invention and, together with the description, serve to explain principles of the present invention. In the figures:

FIG. 1 is a perspective diagram illustrating a semiconductor plasma-processing apparatus in accordance with a preferred embodiment of the invention;

FIG. 2 is a sectional diagram illustrating the semiconductor plasma-processing apparatus in accordance with the preferred embodiment of the invention; and

FIG. 3 is a functional block diagram illustrating the semiconductor plasma-processing apparatus in accordance with the preferred embodiment of the invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. And, there may be further comprised with various additional apparatuses or devices, even without detailed description herein. Like numerals refer to like elements throughout the specification.

Hereinafter, it will be described about an exemplary embodiment of the present invention in conjunction with the accompanying drawings.

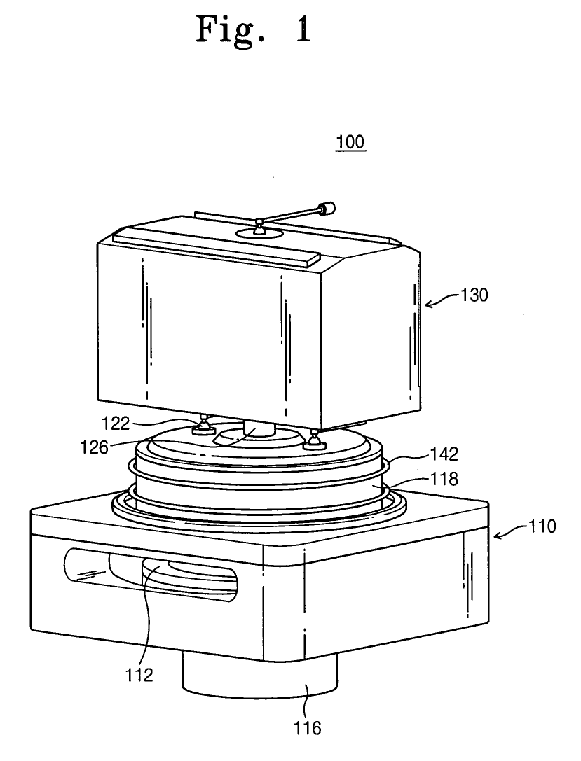

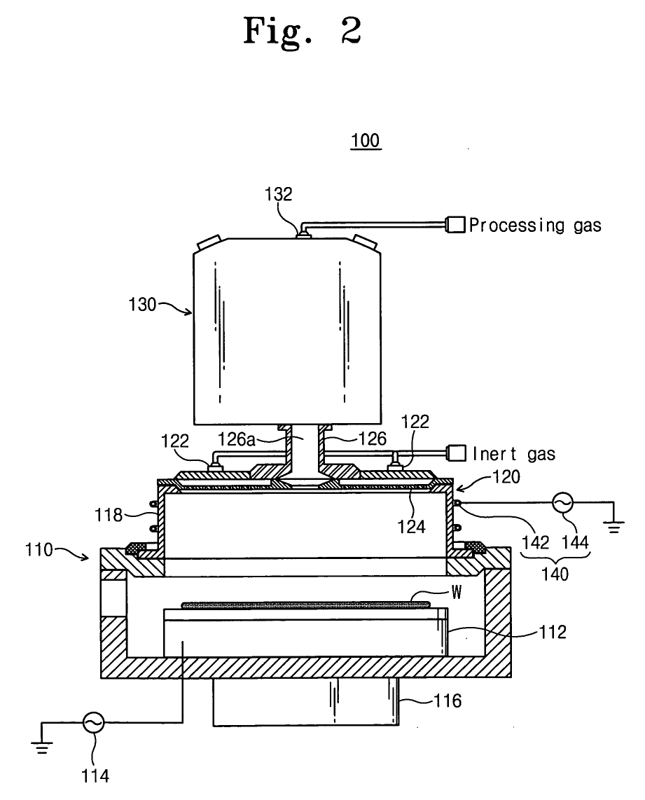

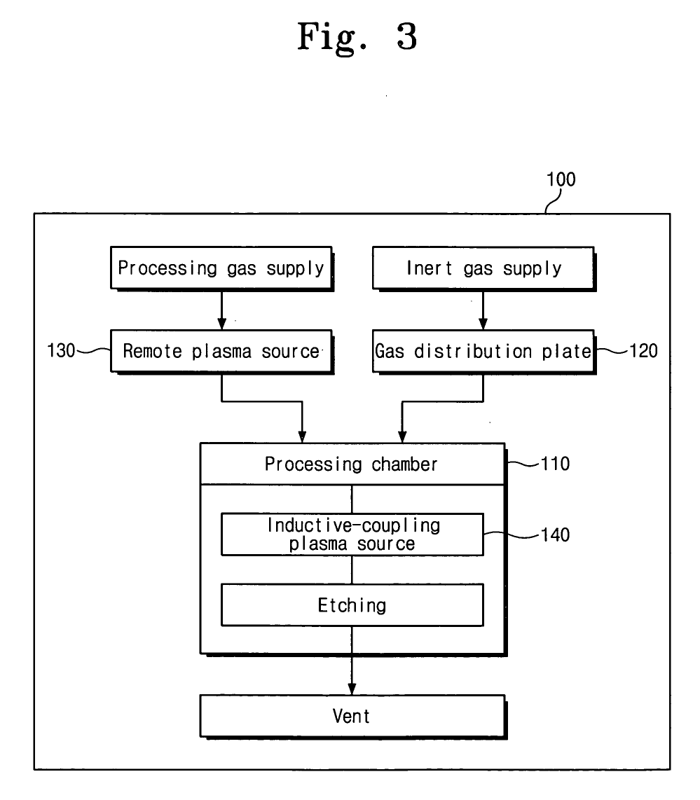

FIG. 1 is a perspective diagram illustrating a semiconductor plasma-processing apparatus in accordance with a preferred embodiment of the invention, and FIG. 2 is a sectional diagram illustrating the semiconductor plasma-processing apparatus in accordance with the preferred embodiment of the invention. FIG. 3 is a functional block diagram illustrating the semiconductor plasma-processing apparatus in accordance with the preferred embodiment of the invention.

As shown in FIGS. 1 through 3, the semiconductor plasma-processing apparatus 100 is a kind of semiconductor manufacturing apparatus for etching or ashing substrate surfaces by means of radicals or ions generated from remote and inductive-coupling plasma sources.

The semiconductor plasma-processing apparatus 100 is comprised of a processing chamber 110 having a space for plasma generation therein. At the downside in the processing chamber 110 is disposed an electrostatic chuck 112 to which an RF power is connected to apply a bias voltage thereto. The bias voltage forces ions and radicals to flow out of the plasma generated in the processing chamber 110, and to collide with the surface of the wafer W in sufficiently high energy. On the bottom of the processing chamber 110, a vacuum sunction pump 116 is disposed with being connected to a vacuum pump (not shown), conditioning the processing chamber 110 in vacuum.

On the topside of the processing chamber 110 is disposed a gas distribution plate (GDP) 120 that includes a couple of gas inlet ports 122 through which an inert gas is supplied. The inert gas flowing through two gas inlet ports 122 is uniformly supplied into the processing chamber 110 by way of ejection holes 124 of the gas distribution plate 120. The gas distribution plate 120 also includes a connection port 126 connecting with a remote plasma source 130 and the connecting port is located in a center of the gas distribution plate 120. Processing gas activated from the remote plasma source 130 is directly supplied into the processing chamber 110 by way of a path 126a of the connection port 126.

The remote plasma source 130 has an inlet port 132 through which the processing gas (e.g., Cl₂, HBr, or CF₄) flows thereinto. The Cl radicals and ions excitingly generated from the remote plasma source 130 are supplied toward the center of the processing chamber 110 through the connection port 126 of the gas distribution plate 120.

The upper sidewall 118 of the processing chamber 110 is formed of a dielectric window so as to transmit the RF power therethrough. A coil antenna 142 of the inductive-coupling plasma source 140 is installed with surrounding the upper sidewall 118 of the processing chamber 110. The coil antenna 142 is connected to the RF power 144, through which an RF current flows. The RF current flowing through the coil antenna 142 induces a magnetic field. According to time variation of the magnetic field, an electric field is generated in the processing chamber 110. The induced electric field ionizes the inert gas, which is flowing into the processing chamber 110, and the processing gas supplied from the remote plasma source 130, resulting in plasma within the processing chamber 110. The plasma generated therein collides with the wafer W, by which the wafer W is etched in a predetermined pattern.

Now, it will be described about an etching process in the semiconductor plasma-processing apparatus according to the present invention.

First, the processing gas (Cl₂, HBr, or CF₄) inactivated is supplied to the remote plasma source 130 through the inlet port 132 thereof. When the RF power is applied to the remote plasma source 130, the processing gas is excited in the remote plasma source 130 and thereby, for example, chlorine (Cl) radicals and ions are generated. The Cl radicals and ions generated in the remote plasma source 130 are supplied toward the center space of the processing chamber 110 by way of the connection port 126. And, the inert gases (e.g., O₂ and N₂) are uniformly supplied into the processing chamber 110 through the ejection holes 124 of the gas distribution plate 120 disposed at the top of the inductive-coupling plasma source 140. These Cl radicals and ions, and the inert gases, being supplied into the processing chamber 110, are generated into ions for the etching process by the inductive-coupling plasma source 140, and put into the etching process together with radicals supplied from the remote plasma source. The Cl radicals generated and supplied from the remote plasma source 130 partially reacts with each other to be stabilized into Cl₂. During this, if the gas is reactivated by the inductive-coupling plasma source 140, it more raises the efficiency of generating the Cl radicals. As such, the Cl radicals affluently generated in the processing chamber 110 activate the etching reaction and enhance an etch rate therein, increasing throughput thereof.

In other words, when the radicals are affluently supplied toward the center of the processing chamber from the remote plasma source, the processing gas sprightly reacts on the wafer together with the plasma generated by the inductive-coupling plasma source, improving the etch rate.

It is conventional that an inductive-coupling plasma source is inefficient in transforming Cl₂ gas as main etching gas into radicals, and the Cl radicals are distributed denser at the sides than the center in the processing chamber. In order to overcome the conventional effect of radical concentration, the plasma-processing apparatus according to the invention has the features with employing the remote plasma source that is installed at the gas injection part on the top of the inductive-coupling plasma source, supplying affluent radicals to the processing chamber 110 from the remote plasma source.

The plasma-processing apparatus by the invention is able to generate Cl radicals as much as increasing an etch rate by means of the remote plasma source, which compensates the shortness of the conventional inductive-coupling plasma source that degrades the efficiency in generating radicals from Cl2 gas.

As described above, the effect of side radical-concentration, which is frequent by an inductive-coupling plasma source, is lessened by radicals supplied from the remote plasma source. The affluent radicals sprightly activate etching reactions to rise an etch rate. Consequently, the semiconductor plasma-processing apparatus according to the invention is advantageous to improving the performance of etching process and the rate of operation.

While there has been illustrated and described what are presently considered to be example embodiments of the present invention, it will be understood by those skilled in the art that various other modifications may be made, and equivalents may be substituted, without departing from the true scope of the invention. Additionally, many modifications may be made to adapt a particular situation to the teachings of the present invention without departing from the central inventive concept described herein. Therefore, it is intended that the present invention not be limited to the particular embodiments disclosed, but that the invention include all embodiments falling within the scope of the appended claims.

What is claimed is:

1. A semiconductor plasma-processing apparatus comprising:
a remote plasma source activating processing gas to generate radicals and ions;
a processing chamber having an inlet port through which the activated processing gas flows into;
a susceptor disposed in the processing chamber, on which a wafer is settled; and
an inductive-coupling plasma source disposed in the processing chamber, providing high-frequency energy to the activated processing gas.

2. The semiconductor plasma-processing apparatus as set forth in claim 1, wherein the inductive-coupling plasma source comprises:
a coil antenna surrounding an upper sidewall of the processing chamber; and
an RF power unit applying RF power to the coil antenna.

3. The semiconductor plasma-processing apparatus as set forth in claim 1, which further comprises a gas distribution plate uniformly supplying an inert gas into the processing chamber and having a gas inlet port disposed at the top of the processing chamber, through which the inert gas is supplied.

4. The semiconductor plasma-processing apparatus as set forth in claim 3, wherein the gas distribution plate comprises a path directly supplying the activated processing gas to the processing chamber from the remote plasma source.

5. A semiconductor plasma-processing apparatus comprising:
a processing chamber including a susceptor on which a wafer is settled;
a first plasma source generating plasma from processing gas before supplying the processing gas into the processing chamber; and
a second plasma source generating plasma from the processing gas that is supplied into the processing chamber after passing through the first plasma source.

6. The semiconductor plasma-processing apparatus as set forth in claim 5, wherein the first plasma source is a remote plasma source to generate radicals by activating the processing gas.

7. The semiconductor plasma-processing apparatus as set forth in claim 6, wherein the first plasma source comprises:
a coil antenna surrounding an upper sidewall of the processing chamber; and
an RF power unit applying RF power to the coil antenna.

8. The semiconductor plasma-processing apparatus as set forth in claim 5, which further comprises:
a gas distribution plate disposed at the top of the processing chamber, uniformly supplying the inert gas into the processing chamber.

9. The semiconductor plasma-processing apparatus as set forth in claim 5, which further comprises a gas distribution plate uniformly supplying an inert gas into the processing chamber and having a gas inlet port disposed at the top of the processing chamber, through which the inert gas is supplied.

10. The semiconductor plasma-processing apparatus as set forth in claim 9, wherein the gas distribution plate comprises a path directly supplying the activated processing gas to the processing chamber from the first plasma source.

11. A method of processing plasma for a semiconductor manufacturing process, comprising:
supplying inactivated processing gas into a remote plasma source;
supplying radicals and ions, which are excited in the remote plasma source, into a processing chamber;
supplying inactivated inert gas into the processing chamber; and
activating the radicals and ions and the inert gas, which are being supplied into the processing chamber, by an inductive-coupling plasma source.

12. The method as set forth in claim 11, wherein the inactivated inert gas is uniformly supplied into the processing chamber through a gas distribution plate.

13. The method as set forth in claim 12, wherein the radicals and ions are supplied into the processing chamber from the remote plasma source, being different from the inert gas in path.
